(19) United States
(12) Patent Application Publication
(10) Pub. No.: US 2024/0405735 A1
(43) Pub. Date: Dec. 5, 2024

(54) RADIO-FREQUENCY CIRCUIT AND COMMUNICATION DEVICE

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/807,034

(22) Filed: Aug. 16, 2024

Related U.S. Application Data
(63) Continuation of application No. PCT/JP2023/004061, filed on Feb. 7, 2023.

(30) Foreign Application Priority Data
Feb. 17, 2022 (JP) 2022-022997

(51) Int. Cl. H03F 3/24; H03F 1/02; H04B 1/00

(52) U.S. Cl. CPC H03F 3/245; H03F 1/0288; H04B 1/0053; H03F 2200/451

(57) ABSTRACT

A radio-frequency circuit includes a carrier amplifier configured to amplify radio-frequency signals in a band A, a carrier amplifier configured to amplify radio-frequency signals in a band B, peak amplifiers configured to amplify radio-frequency signals in the band A and radio-frequency signals in the band B, a transformer having an input-side coil and an output-side coil, and phase shift lines.

### CROSS-REFERENCE TO RELATED APPLICATIONS

The present application is a continuation application of PCT International Application No. PCT/JP2023/004061 filed on Feb. 7, 2023, designating the United States of America, which is based on and claims priority to Japanese patent application JP 2022-022997, filed Feb. 17, 2022.The entire disclosures of the above-identified applications, including the specifications, the drawings, and the claims are incorporated herein by reference in their entirety.

### BACKGROUND

A radio-frequency circuit (power amplifier circuit) including a first amplifier (carrier amplifier) configured to amplify a first signal that is split from an input signal assuming the power level of the input signal is within a region greater than or equal to a first level and to output a second signal, a first transformer configured to receive the second signal, a second amplifier (peak amplifier) configured to amplify a third signal that is split from an input signal assuming the power level of the input signal is within a region greater than or equal to a second level higher than the first level and to output a fourth signal, and a second transformer configured to receive the fourth signal.

### SUMMARY OF DISCLOSURE

A radio-frequency circuit according to an exemplary embodiment of the present disclosure includes a first carrier amplifier configured to amplify a radio-frequency signal in a first band, a second carrier amplifier configured to amplify a radio-frequency signal in a second band, a first peak amplifier configured to amplify a radio-frequency signal in the first band and a radio-frequency signal in the second band, a second peak amplifier configured to amplify a radio-frequency signal in the first band and a radio-frequency signal in the second band, a transformer having an input-side coil and an output-side coil, and a first phase shifter circuit and a second phase shifter circuit. An output terminal of the first peak amplifier is coupled to one end of the input-side coil. An output terminal of the second peak amplifier is coupled to another end of the input-side coil. An output terminal of the first carrier amplifier is coupled to one end of the first phase shifter circuit. An output terminal of the second carrier amplifier is coupled to one end of the second phase shifter circuit. Another end of the first phase shifter circuit is coupled to one end of the output-side coil. Another end of the second phase shifter circuit is coupled to another end of the output-side coil.

### EFFECTS OF DISCLOSURE

The present disclosure provides a miniaturized radio-frequency circuit and a miniaturized communication device that are capable of amplifying radio-frequency signals in multiple bands.

### BRIEF DESCRIPTION OF DRAWINGS

FIG. 1 is a circuit configuration diagram of a radio-frequency circuit and a communication device according to an exemplary embodiment.

FIG. 2A is a circuit state diagram of the radio-frequency circuit according to the exemplary embodiment, in the case of transmitting signals in a band A in the high-power mode.

FIG. 2B is a circuit state diagram of the radio-frequency circuit according to the exemplary embodiment, in the case of transmitting signals in the band A in the middle/low-power mode.

FIG. 3A is a circuit state diagram of the radio-frequency circuit according to the exemplary embodiment, in the case of transmitting signals in a band B in the high-power mode.

FIG. 3B is a circuit state diagram of the radio-frequency circuit according to the exemplary embodiment, in the case of transmitting signals in the band B in the middle/low-power mode.

FIG. 4 is a circuit configuration diagram of a radio-frequency circuit according to a comparative example.

FIG. 5A is a graph illustrating the relationship between output power and efficiency in a first pattern of a power amplifier circuit according to the exemplary embodiment.

FIG. 5B is a graph illustrating the relationship between output power and efficiency in a second pattern of the power amplifier circuit according to the exemplary embodiment.

FIG. 5C is a graph illustrating the relationship between output power and efficiency in a third pattern of the power amplifier circuit according to the exemplary embodiment.

FIG. 6 is a circuit configuration diagram of a radio-frequency circuit according to a modification.

FIG. 7 provides a plan view and a sectional view of the radio-frequency circuit according to the exemplary embodiment.

FIG. 8 is a plan view of the radio-frequency circuit according to the modification.

### DESCRIPTION OF EXEMPLARY EMBODIMENTS

To amplify radio-frequency signals of multiple bands using the radio-frequency circuit, it is necessary to incorporate the same number of power amplifier circuits each including the first amplifier (carrier amplifier) and the second amplifier (peak amplifier) as the number of bands. This may result in enlarging the radio-frequency circuit.

The present disclosure has been made to solve the problem described above, and an object thereof is to provide a miniaturized radio-frequency circuit and a miniaturized communication device that are capable of amplifying radio-frequency signals in multiple bands.

### Solution to Problem

Hereinafter, exemplary embodiments of the present disclosure will be described in detail. It should be noted that the exemplary embodiments described below provide comprehensive or specific examples. Specifics including numerical values, shapes, materials, constituent elements, arrangements of the constituent elements, and modes of connection given in the following exemplary embodiments are merely examples and are not intended to limit the present disclosure. Among the constituent elements in the following exemplary embodiments and modifications, constituent elements not recited in any of the independent claims are described as arbitrary constituent elements. The size or size ratio of the constituent elements illustrated in the drawings is not necessarily presented in an exact manner. Like reference symbols denote substantially like configuration elements in the drawings, and redundant descriptions thereof can be omitted or simplified.

In the following description, words used to express relationships between elements, such as parallel and vertical, words used to express the shape of an element, such as rectangular, and numerical ranges do not necessarily denote the exact meanings but denote substantially the same meanings involving, for example, several percent differences.

In the drawings described below, the x-axis and the y-axis are axes perpendicular to each other in a plane parallel to major surfaces of a module substrate. Specifically, assuming the module substrate is rectangular in plan view, the x-axis is parallel to a first side of the module substrate, and the y-axis is parallel to a second side perpendicular to the first side of the module substrate. The z-axis is perpendicular to the major surfaces of the module substrate. Along the z-axis, the positive direction indicates upward, and the negative direction indicates downward.

In the circuit configurations of the present disclosure, the term “couple” applies assuming one circuit element is directly coupled to another circuit element via a connection terminal and/or an interconnect conductor. The term also applies assuming one circuit element is electrically coupled to another circuit element via still another circuit element. The term “coupled between A and B” refers to a situation where one circuit element is positioned between A and B and coupled to both A and B. The term applies assuming the circuit element is coupled in series in the path connecting A and B and also assuming the circuit element is coupled in parallel (shunt-coupled) between the path and ground.

In the component layouts of the present disclosure, the term “plan view of a module substrate” refers to a situation in which an object is orthogonally projected onto an xy-plane and viewed from the positive side of the z-axis. The expression “A is disposed between B and C” refers to a situation in which at least one of the line segments each connecting any given point within B to any given point within C passes through A. The term “the distance between A and B in a plan view of a module substrate” refers to the length of the line segment connecting a representative point in the region of A orthogonally projected onto an xy-plane and a representative point in the region of B orthogonally projected onto the xy-plane. As used herein, a representative point can be, but is not limited to, the center point of a region or the point closest to the opposing region. Terms describing relationships between elements, such as “parallel” and “vertical”, terms indicating an element's shape, such as “rectangular”, and numerical ranges are not meant to convey only precise meanings. These terms and numerical ranges denote meanings that are substantially the same, involving, for example, about several percent differences.

In the component layouts of the present disclosure, the expression “a component is disposed at a substrate” applies assuming the component is disposed at a major surface of the substrate and also assuming the component is disposed inside the substrate. The expression “a component is disposed at a major surface of a substrate” applies assuming the component is disposed in contact with the major surface of the substrate and also assuming the component is disposed above the major surface without making contact with the major surface (for example, assuming the component is stacked on another component that is disposed in contact with the major surface). The expression “a component is disposed at a major surface of a substrate” may include the case in which the component is disposed in a depressed portion formed at the major surface. The expression “a component is disposed within a substrate” includes the case in which the component is encapsulated in the module substrate. The expression also includes the case in which the component is entirely positioned between the two major surfaces of the substrate but not fully covered by the substrate. The expression further includes the case in which only a portion of the component is disposed within the substrate.

In the present disclosure, the term “signal path” refers to a transfer line formed by, for example, a wire line for transferring radio-frequency signals, an electrode directly coupled to the wire line, and a terminal directly coupled to the wire line or electrode.

### Exemplary Embodiment

### [1. Circuit Configuration of Radio-Frequency Circuit 1 and Communication Device 4]

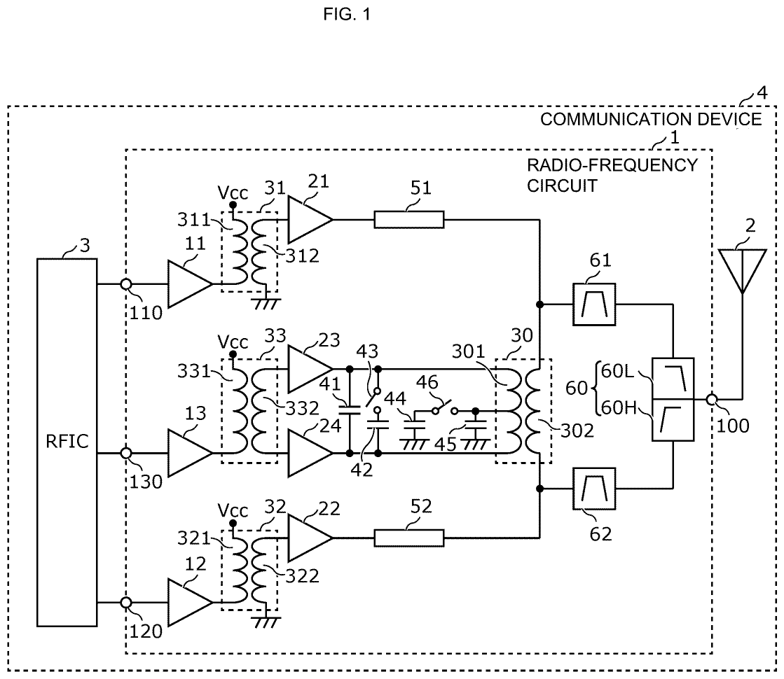

A circuit configuration of a radio-frequency circuit 1 and a communication device 4 according to the present exemplary embodiment will be described with reference to FIG. 1. FIG. 1 is a circuit configuration diagram of the radio-frequency circuit 1 and the communication device 4 according to the exemplary embodiment.

### [1.1 Circuit Configuration of Communication Device 4]

First, a circuit configuration of the communication device 4 will be described. As illustrated in FIG. 1, the communication device 4 according to the present exemplary embodiment includes the radio-frequency circuit 1, an antenna 2, and a radio-frequency (RF) signal processing circuit (RFIC) 3.

The radio-frequency circuit 1 is operable to transfer radio-frequency signals between the antenna 2 and the RFIC 3. A detailed circuit configuration of the radio-frequency circuit 1 will be described later.

The antenna 2 is coupled to an antenna connection terminal 100 of the radio-frequency circuit 1. The antenna 2 is operable to transmit a radio-frequency signal outputted from the radio-frequency circuit 1 and to receive a radio-frequency signal from outside and output the radio-frequency signal to the radio-frequency circuit 1.

The RFIC 3 is an example of a signal processing circuit for processing radio-frequency signals. Specifically, the RFIC 3 is operable to process, for example by down-conversion, receive signals inputted through receive paths of the radio-frequency circuit 1 and output the receive signals generated through the signal processing to a baseband signal integrated circuit (BBIC). The RFIC 3 is also operable to process, for example by up-conversion, transmit signals input from the BBIC and output the transmit signals generated by the signal processing to transmit paths of the radio-frequency circuit 1. The RFIC 3 includes a control unit for controlling elements included in the radio-frequency circuit 1, such as switches, amplifier elements, and bias circuits. The function of the control unit of the RFIC 3 may be partially or entirely implemented outside the RFIC 3; for example, the function of the control unit of the RFIC 3 may be implemented in the BBIC or the radio-frequency circuit 1.

The RFIC 3 also functions as a control unit for controlling a supply voltage and a bias voltage to be supplied to amplifiers included in the radio-frequency circuit 1. Specifically, the RFIC 3 outputs digital control signals to the radio-frequency circuit 1. The supply voltage and bias voltage controlled via the digital control signals can be supplied to the amplifiers of the radio-frequency circuit 1.

The control unit may be included as an amplifier control circuit in the radio-frequency circuit 1. In this case, the amplifier control circuit outputs control signals to control the supply voltage and bias current to power supply circuits and bias circuits, based on the control signals received from the RFIC 3.

Based on the band (frequency range) being used, the RFIC 3 determines to which of input terminals 110 to 130 included in the radio-frequency circuit 1 the RFIC 3 is to output radio-frequency signals.

In the communication device 4 according to the present exemplary embodiment, the antenna 2 may be an optional constituent element.

### [1.2 Circuit Configuration of Radio-Frequency Circuit 1]

Next, a circuit configuration of the radio-frequency circuit 1 will be described. As illustrated in FIG. 1, the radio-frequency circuit 1 includes preamplifiers 11, 12, and 13, carrier amplifiers 21 and 22, peak amplifiers 23 and 24, transformers 30, 31, 32, and 33, capacitors 41, 42, 44, and 45, switches 43 and 46, phase shift lines 51 and 52, filters 61 and 62, a diplexer 60, input terminals 110, 120, and 130, and an antenna connection terminal 100. In the radio-frequency circuit 1, the preamplifiers 11, 12, and 13, the carrier amplifiers 21 and 22, the peak amplifiers 23 and 24, the transformers 30, 31, 32, and 33, the capacitors 41, 42, 44, and 45, the switches 43 and 46, and the phase shift lines 51 and 52 constitute a Doherty amplifier circuit.

A Doherty amplifier circuit refers to an amplifier circuit designed to achieve high efficiency by using multiple amplifiers as carrier amplifiers and peak amplifiers. A carrier amplifier refers to an amplifier capable of operating in a Doherty amplifier circuit irrespective of whether the power of radio-frequency signals (input) is high or low. A peak amplifier refers to an amplifier capable of operating in a Doherty amplifier circuit mainly assuming the power of radio-frequency signals (input) is relatively high. Thus, assuming the input power of radio-frequency signals is relatively low, the carrier amplifier mainly amplifies radio-frequency signals; assuming the input power of radio-frequency signals is relatively high, both of the carrier amplifier and the peak amplifier amplify radio-frequency signals. By operating in this manner, the load impedance observed from the carrier amplifier increases in the Doherty amplifier circuit at low output power. As a result, the efficiency at low output power is improved.

In the radio-frequency circuit according to the present disclosure, assuming the current of the output signal from the carrier amplifier and the current of the output signal from the peak amplifier are combined, the carrier amplifier is identified as the one having an output terminal coupled to a phase shifter circuit that shifts the phase of radio-frequency signals by ¼ wavelength, while the peak amplifier is identified as the one having an output terminal not coupled to a phase shifter circuit that shifts the phase of radio-frequency signals by ¼ wavelength.

The input terminal 110 is coupled to the RFIC 3 to receive the radio-frequency signals in a band A output from the RFIC 3. The input terminal 120 is coupled to the RFIC 3 to receive the radio-frequency signals in a band B output from the RFIC 3. The input terminal 130 is coupled to the RFIC 3 to receive the radio-frequency signals in the band A or B output from the RFIC 3. The antenna connection terminal 100 is coupled to the antenna 2.

Each of the input terminals 110 to 130 and the antenna connection terminal 100 may be a metal conductor such as a metal electrode or metal bump or may be a point in a metal wire line.

The preamplifier 11 is operable to amplify the radio-frequency signals in the band A (first band) input from the input terminal 110. The preamplifier 12 is operable to amplify the radio-frequency signals in the band B (second band) input from the input terminal 120. The preamplifier 13 is operable to amplify the radio-frequency signals in the band A or B input from the input terminal 130.

The transformer 31 has a primary coil 311 and a secondary coil 312. One end of the primary coil 311 is coupled to a power supply (a supply voltage Vcc), and the other end of the primary coil 311 is coupled to the output terminal of the preamplifier 11. One end of the secondary coil 312 is coupled to the input terminal of the carrier amplifier 21, and the other end of the secondary coil 312 is coupled to ground. The transformer 31 is operable to provide impedance matching between the preamplifier 11 and the carrier amplifier 21. This configuration transfers the radio-frequency signals input from the input terminal 110 over a wide range.

The transformer 32 has a primary coil 321 and a secondary coil 322. One end of the primary coil 321 is coupled to the power supply (the supply voltage Vcc), and the other end of the primary coil 321 is coupled to the output terminal of the preamplifier 12. One end of the secondary coil 322 is coupled to the input terminal of the carrier amplifier 22, and the other end of the secondary coil 322 is coupled to ground. The transformer 32 is operable to provide impedance matching between the preamplifier 12 and the carrier amplifier 22. This configuration transfers the radio-frequency signals input from the input terminal 120 over a wide range.

The transformer 33 has a primary coil 331 and a secondary coil 332. One end of the primary coil 331 is coupled to the power supply (the supply voltage Vcc), and the other end of the primary coil 331 is coupled to the output terminal of the preamplifier 13. One end of the secondary coil 332 is coupled to the input terminal of the peak amplifier 23, and the other end of the secondary coil 332 is coupled to the input terminal of the peak amplifier 24. The transformer 33 is operable to split the radio-frequency signal output from the preamplifier 13 into two radio-frequency signals having opposite phases. The two split radio-frequency signals are respectively input to the peak amplifiers 23 and 24. The transformer 33 is also operable to provide impedance matching between the preamplifier 13 and the peak amplifiers 23 and 24. This configuration transfers the radio-frequency signals input from the input terminal 130 over a wide range.

Phase shifter circuits may be provided in place of the transformers 31 to 33. It may be possible that the transformers 31 to 33 and the preamplifiers 11 to 13 are not incorporated.

The carrier amplifier 21 is an example of a first carrier amplifier. The carrier amplifier 21 includes an amplifier transistor. The carrier amplifier 22 is an example of a second carrier amplifier. The carrier amplifier 22 includes an amplifier transistor. The peak amplifier 23 is an example of a first peak amplifier. The peak amplifier 23 includes an amplifier transistor. The peak amplifier 24 is an example of a second peak amplifier. The peak amplifier 24 includes an amplifier transistor. The amplifier transistors included in the carrier amplifiers and peak amplifiers described above are, for example, bipolar transistors, such as heterojunction bipolar transistors (HBTs), or field-effect transistors, such as metal-oxide-semiconductor field-effect transistors (MOSFETs).

The carrier amplifier 21 is a Class-A (or Class-AB) amplifier circuit capable of amplification for all power levels of signals in the band A (first band) output from the transformer 31. The carrier amplifier 21 is capable of highly efficient amplification especially in the low power output region and the middle power output region. The carrier amplifier 22 is a Class-A (or Class-AB) amplifier circuit capable of amplification for all power levels of signals in the band B (second band) output from the transformer 32. The carrier amplifier 22 is capable of highly efficient amplification especially in the low power output region and the middle power output region.

Each of the peak amplifiers 23 and 24 is a Class-C amplifier circuit capable of amplification in the relatively high power level region of signals in the band A or B output from the transformer 33. The amplifier transistors included in the peak amplifiers 23 and 24 are configured to receive a bias voltage lower than a bias voltage applied to the amplifier transistors included in the carrier amplifiers 21 and 22. As a result, as the power level of signals output from the transformer 33 increases, the output impedance decreases. With this configuration, the peak amplifiers 23 and 24 are able to provide low-distortion amplification in the high power output region.

The output terminal of the carrier amplifier 21 is coupled to one end of the phase shift line 51. The output terminal of the carrier amplifier 22 is coupled to one end of the phase shift line 52.

The transformer 30 has an input-side coil 301 and an output-side coil 302. One end of the input-side coil 301 is coupled to the output terminal of the peak amplifier 23, and the other end of the input-side coil 301 is coupled to the output terminal of the peak amplifier 24. One end of the output-side coil 302 is coupled to the other end of the phase shift line 51, and the other end of the output-side coil 302 is coupled to the other end of the phase shift line 52.

The phase shift line 51 is an example of a first phase shifter circuit. The phase shift line 51 is, for example, a quarter-wavelength transfer line. The phase shift line 51 is operable to delay the phase of radio-frequency signals input from one end of the phase shift line 51 by ¼ wavelength and output the radio-frequency signals from the other end of the phase shift line 51. One end of the phase shift line 51 is coupled to the output terminal of the carrier amplifier 21, and the other end of the phase shift line 51 is coupled to one end of the output-side coil 302.

The phase shift line 52 is an example of a second phase shifter circuit. The phase shift line 52 is, for example, a quarter-wavelength transfer line. The phase shift line 52 is operable to delays the phase of radio-frequency signals input from one end of the phase shift line 52 by ¼ wavelength and output the radio-frequency signals from the other end of the phase shift line 52. One end of the phase shift line 52 is coupled to the output terminal of the carrier amplifier 22, and the other end of the phase shift line 52 is coupled to the other end of the output-side coil 302.

The first phase shifter circuit and the second phase shifter circuit are not necessarily implemented in the form of phase shift lines. The first phase shifter circuit and the second phase shifter circuit may be, for example, circuits formed by chip inductors and capacitors. More specifically, each of the first phase shifter circuit and the second phase shifter circuit may be an LC circuit including two inductors coupled in series with each other and a capacitor coupled between the node of the two inductors and ground. Each of the first phase shifter circuit and the second phase shifter circuit may be an LC circuit including two capacitors coupled in series with each other, an inductor coupled between one end of one capacitor of the two capacitors and ground, and an inductor coupled between the other end of the one capacitor and ground.

The capacitor 41 has one end (one terminal) coupled to the output terminal of peak amplifier 23 and the other end (the other terminal) coupled to the output terminal of peak amplifier 24.

The capacitor 42 is an example of a first capacitor. The capacitor 42 is coupled between the output terminal of the peak amplifier 23 and the output terminal of the peak amplifier 24. The switch 43 is an example of a first switch. The switch 43 is coupled between the output terminal of the peak amplifier 23 and the output terminal of the peak amplifier 24 and is coupled in series with the capacitor 42.

The capacitors 41 and 42 and the switch 43 function to hinder harmonic waves output from the peak amplifiers 23 and 24 from traveling to the transformer 30. In the present exemplary embodiment, assuming the switch 43 is closed, the capacitors 41 and 42 form a combined parallel capacitance between the output terminal of the peak amplifier 23 and the output terminal of the peak amplifier 24, thereby suppressing harmonic waves in the band A. In the present exemplary embodiment, assuming the switch 43 is open, the capacitor 41 forms a single capacitance between the output terminal of the peak amplifier 23 and the output terminal of the peak amplifier 24, thereby suppressing harmonic waves in the band B.

In other words, to transfer radio-frequency signals in the band A, the switch 43 is closed, and to transfer radio-frequency signals in the band B, the switch 43 is open. This configuration suppresses harmonic waves in a specific band of interest, thereby widening the range of radio-frequency signals that can be transferred.

The switch 43 and the capacitor 42 may be coupled in parallel instead of in series, and a parallel connection circuit of the switch 43 and the capacitor 42, as well as the capacitor 41, may be coupled in series between the output terminal of the peak amplifier 23 and the output terminal of the peak amplifier 24. In this case, a single capacitance of the capacitor 41 is formed assuming the switch 43 is closed, and a combined series capacitance of the capacitors 41 and 42 is formed assuming the switch 43 is open.

It may be possible that the capacitor 41 is not incorporated. In this case, the harmonic waves in either the band A or B can be suppressed by turning the switch 43 on or off.

The capacitor 45 has one end (one terminal) coupled near the midpoint of the input-side coil 301 and the other end (the other terminal) coupled to ground.

The capacitor 44 is an example of a second capacitor. The capacitor 44 has one end (one terminal) coupled near the midpoint of the input-side coil 301 via the switch 46 and the other end (the other terminal) coupled to ground. The switch 46 is an example of a second switch. The switch 46 is coupled between the point near the midpoint of the input-side coil 301 and ground, in series with the capacitor 44.

The capacitors 44 and 45 and the switch 46 function to reduce common mode noise generated in the peak amplifiers 23 and 24. In the present exemplary embodiment, a combined parallel capacitance of the capacitors 44 and 45 is formed between the input-side coil 301 and ground by closing the switch 46, thereby reducing common mode noise in the band A. By contrast, a single capacitance of the capacitor 45 is formed between the input-side coil 301 and ground by opening the switch 46, thereby reducing common mode noise in the band B.

In other words, to transfer radio-frequency signals in the band A, the switch 46 is closed, and to transfer radio-frequency signals in the band B, the switch 46 is open. This configuration reduces common mode noise in a specific band of interest, thereby widening the range of radio-frequency signals that can be transferred.

The switch 46 and the capacitor 44 may be coupled in parallel instead of in series, and a parallel connection circuit of the switch 46 and the capacitor 44, as well as the capacitor 45, may be coupled in series between the input-side coil 301 and ground. In this case, a single capacitance of the capacitor 45 is formed assuming the switch 46 is closed, and a combined series capacitance of the capacitors 44 and 45 is formed assuming the switch 46 is open.

It may be possible that the path connecting the input-side coil 301 and ground via the capacitor 45 is not provided. In this case, common mode noise in either the band A or B can be reduced by turning the switch 46 on or off.

The filter 61 is an example of a first filter. The filter 61 is coupled between one end of the output-side coil 302 and the antenna connection terminal 100. The filter 61 has a pass band including the band A. The filter 62 is an example of a second filter. The filter 62 is coupled between the other end of the output-side coil 302 and the antenna connection terminal 100. The filter 62 has a pass band including the band B. The filters 61 and 62 improve the signal quality of radio-frequency signals in the bands A and B output from the antenna connection terminal 100.

The diplexer 60 includes a high pass filter 60H and a low pass filter 60L. One terminal of the high pass filter 60H and one terminal of the low pass filter 60L are coupled to the antenna connection terminal 100. The other terminal of the low pass filter 60L is coupled to the filter 61. The other terminal of the high pass filter 60H is coupled to the filter 62. The low pass filter 60L is a low pass filter that has a pass band including the band A. The high pass filter 60H is a high pass filter that has a pass band including the band B.

With this connection configuration of the radio-frequency circuit 1, the current of a signal in the band A output from the carrier amplifier 21 and the currents of differential signals in the band A output from the peak amplifiers 23 and 24 are combined, and the combined output signal is output to the filter 61. The current of a signal in the band B output from the carrier amplifier 22 and the currents of differential signals in the band B output from the peak amplifiers 23 and 24 are combined, and the combined output signal is output to the filter 62.

The bands A and B are frequency bands for communication systems built using a radio access technology (RAT). The bands A and B are defined by standardization organizations such as the 3rd Generation Partnership Project (3GPP) (registered trademark) and the Institute of Electrical and Electronics Engineers (IEEE). Examples of the communication systems include a 5th Generation New Radio (5GNR) system, a Long-Term Evolution (LTE) system, and a wireless local area network (WLAN) system.

In the radio-frequency circuit 1 according to the present exemplary embodiment, the band A corresponds to, for example, 5G-NR n77 (3300-4200 MHz), and the band B corresponds to, for example, 5G-NR n79 (4400-5000 MHz).

It is sufficient for the radio-frequency circuit 1 according to the present exemplary embodiment to include the carrier amplifiers 21 and 22, the peak amplifiers 23 and 24, the transformer 30, and the phase shift lines 51 and 52. The preamplifiers 11 to 13, the transformers 31 to 33, the capacitors 41 to 45, the switches 43 and 46, the filters 61 and 62, and the diplexer 60 are optional constituent elements in the radio-frequency circuit according to the present disclosure.

### [1.3 Radio-Frequency Signal Flow in Radio-Frequency Circuit 1]

Next, the flows of radio-frequency signals in the bands A and B in the radio-frequency circuit 1 will be described.

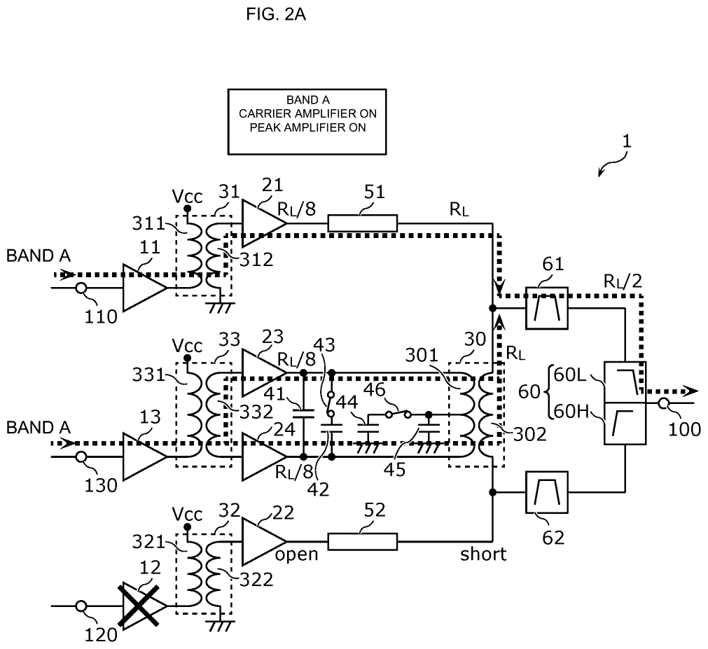

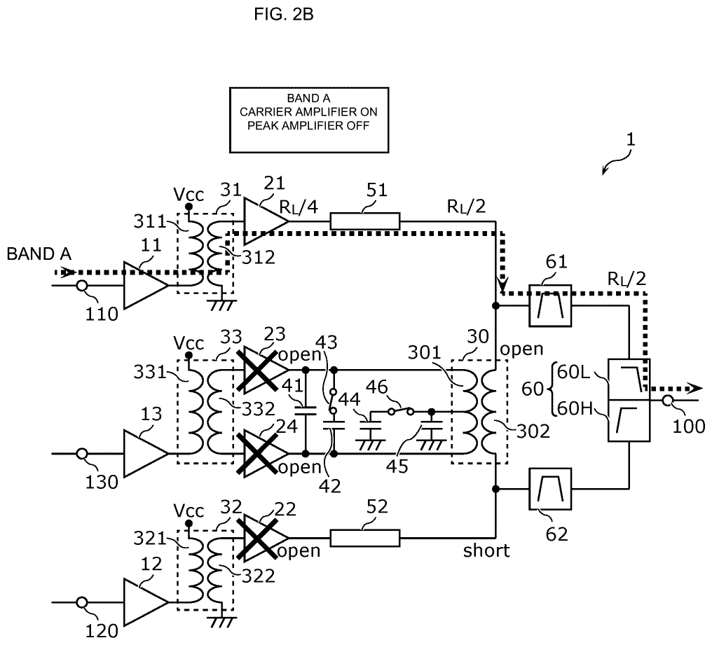

FIG. 2A is a circuit state diagram of the radio-frequency circuit 1 according to the exemplary embodiment, in the case of transmitting signals in the band A in the high-power mode. FIG. 2B is a circuit state diagram of the radio-frequency circuit 1 according to the exemplary embodiment, in the case of transmitting signals in the band A in the middle/low-power mode.

First, as illustrated in FIG. 2A, assuming the radio-frequency circuit 1 transfers signals in the band A in the high-power mode, the carrier amplifier 21 operates in amplification (Class A or Class AB operation), and the peak amplifiers 23 and 24 operate in differential amplification (Class C operation). The switches 43 and 46 are closed.

In this case, the band-A signals transferred through the input terminal 110, the preamplifier 11, the transformer 31, the carrier amplifier 21, and the phase shift line 51 are combined with the band-A signals transferred through the input terminal 130, the preamplifier 13, the transformer 33, the peak amplifiers 23 and 24, and the transformer 30. The combined band-A signals are output from the antenna connection terminal 100 via the filter 61 and the low pass filter 60L.

Provided that the impedance of the load coupled to the antenna connection terminal 100 is R_{L}/2, the impedance assuming the load side is observed from the other end of the phase shift line 51 and the impedance assuming the load side is observed from the one end of the output-side coil 302 are both R_{L}. The output impedance of the carrier amplifier 21 is R_{L}/8, altered by the phase shift line 51 from the impedance assuming the load side is observed from the other end of the phase shift line 51. The output impedance of the peak amplifiers 23 and 24 is R_{L}/8, altered by the transformer 30 from the impedance assuming the load side is observed from the one end of the output-side coil 302 (with a voltage conversion ratio of 1:2).

At this time, no radio-frequency signals in the band A are output from the RFIC 3 to the input terminal 120, and the carrier amplifier 22 does not operate in amplification. As a result, the output impedance of the carrier amplifier 22 becomes open, and the impedance at the other end of the output-side coil 302 is shorted by the phase shift line 52.

Next, as illustrated in FIG. 2B, assuming the radio-frequency circuit 1 transfers signals in the band A in the middle/low-power mode, the carrier amplifier 21 operates in amplification (Class A or Class AB operation), and the peak amplifiers 23 and 24 do not operate in amplification. The switches 43 and 46 are closed.

In this case, the band-A signals transferred through the input terminal 110, the preamplifier 11, the transformer 31, the carrier amplifier 21, and the phase shift line 51 are output from the antenna connection terminal 100 via the filter 61 and the low pass filter 60L.

Provided that the impedance of the load coupled to the antenna connection terminal 100 is R_{L}/2, the impedance assuming the load side is observed from the other end of the phase shift line 51 is R_{L}/2. The output impedance of the carrier amplifier 21 is R_{L}/4, altered by the phase shift line 51 from the impedance assuming the load side is observed from the other end of the phase shift line 51. Because the peak amplifiers 23 and 24 do not operate in amplification, the output impedance of the peak amplifiers 23 and 24 is open.

At this time, no radio-frequency signals in the band A are output from the RFIC 3 to the input terminal 120, and the carrier amplifier 22 does not operate in amplification. As a result, the output impedance of the carrier amplifier 22 becomes open, and the impedance at the other end of the output-side coil 302 is shorted by the phase shift line 52.

Assuming transferring signals in the band A, the output impedance of the carrier amplifier 21 is twice as large in the middle/low-power mode as in the high-power mode. In other words, in the middle/low-power mode, the peak amplifiers 23 and 24 are turned off, and the output impedance of the carrier amplifier 21 increases. As a result, the radio-frequency circuit 1 operates at high efficiency.

By contrast, in the high-power mode, the carrier amplifier 21 and the peak amplifiers 23 and 24 operate to output high-power signals, and the output impedances of the carrier amplifier 21 and the peak amplifiers 23 and 24 are relatively low. As a result, signal distortion is suppressed.

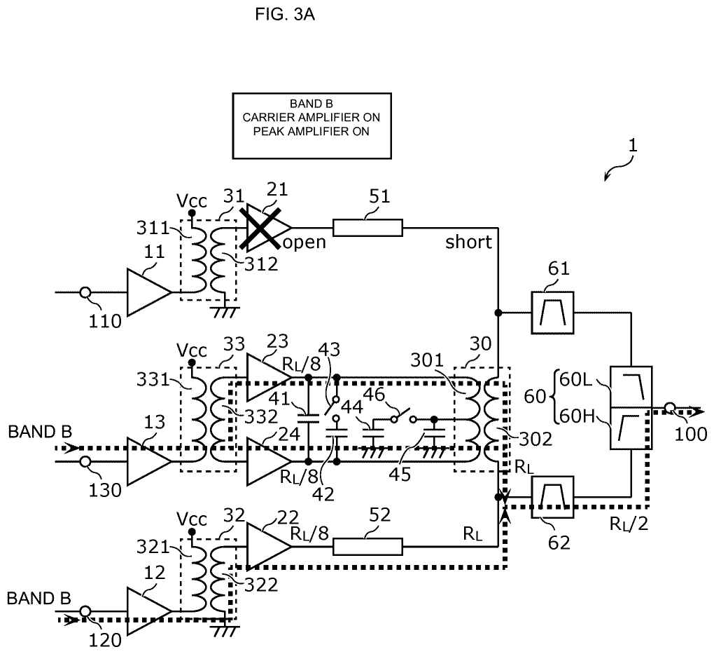

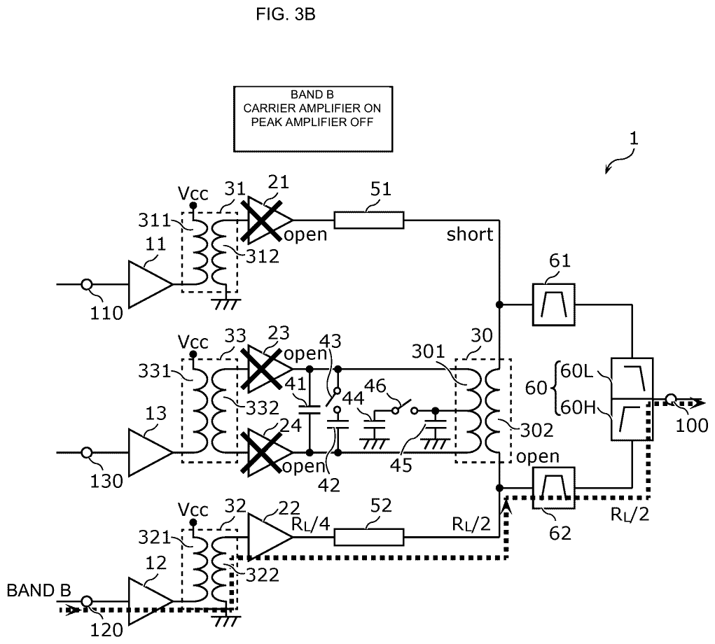

FIG. 3A is a circuit state diagram of the radio-frequency circuit 1 according to the exemplary embodiment, in the case of transmitting signals in the band B in the high-power mode. FIG. 3B is a circuit state diagram of the radio-frequency circuit 1 according to the exemplary embodiment, in the case of transmitting signals in the band B in the middle/low-power mode.

First, as illustrated in FIG. 3A, assuming the radio-frequency circuit 1 transfers signals in the band B in the high-power mode, the carrier amplifier 22 operates in amplification (Class A or Class AB operation), and the peak amplifiers 23 and 24 operate in differential amplification (Class C operation). The switches 43 and 46 are open.

In this case, the band-B signals transferred through the input terminal 120, the preamplifier 12, the transformer 32, the carrier amplifier 22, and the phase shift line 52 are combined with the band-B signals transferred through the input terminal 130, the preamplifier 13, the transformer 33, the peak amplifiers 23 and 24, and the transformer 30. The combined band-B signals are output from the antenna connection terminal 100 via the filter 62 and the high pass filter 60H.

Provided that the impedance of the load coupled to the antenna connection terminal 100 is R_{L}/2, the impedance assuming the load side is observed from the other end of the phase shift line 52 and the impedance assuming the load side is observed from the other end of the output-side coil 302 are both R_{L}. The output impedance of the carrier amplifier 22 is R_{L}/8, altered by the phase shift line 52 from the impedance assuming the load side is observed from the other end of the phase shift line 52. The output impedance of the peak amplifiers 23 and 24 is R_{L}/8, altered by the transformer 30 from the impedance assuming the load side is observed from the other end of the output-side coil 302 (with a voltage conversion ratio of 1:2).

At this time, no radio-frequency signals in the band B are output from the RFIC 3 to the input terminal 110, and the carrier amplifier 21 does not operate in amplification. As a result, the output impedance of the carrier amplifier 21 becomes open, and the impedance at the one end of the output-side coil 302 is shorted by the phase shift line 51.

Next, as illustrated in FIG. 3B, assuming the radio-frequency circuit 1 transfers signals in the band B in the middle/low-power mode, the carrier amplifier 22 operates in amplification (Class A or Class AB operation), and the peak amplifiers 23 and 24 do not operate in amplification. The switches 43 and 46 are open.

In this case, the band-B signals transferred through the input terminal 120, the preamplifier 12, the transformer 32, the carrier amplifier 22, and the phase shift line 52 are output from the antenna connection terminal 100 via the filter 62 and the high pass filter 60H.

Provided that the impedance of the load coupled to the antenna connection terminal 100 is R_{L}/2, the impedance assuming the load side is observed from the other end of the phase shift line 52 is R_{L}/2. The output impedance of the carrier amplifier 22 is R_{L}/4, altered by the phase shift line 52 from the impedance assuming the load side is observed from the other end of the phase shift line 52. Because the peak amplifiers 23 and 24 do not operate in amplification, the output impedance of the peak amplifiers 23 and 24 is open.

At this time, no radio-frequency signals in the band B are output from the RFIC 3 to the input terminal 110, and the carrier amplifier 21 does not operate in amplification. As a result, the output impedance of the carrier amplifier 21 becomes open, and the impedance at the one end of the output-side coil 302 is shorted by the phase shift line 51.

Assuming transferring signals in the band B, the output impedance of the carrier amplifier 22 is twice as large in the middle/low-power mode as in the high-power mode. In other words, in the middle/low-power mode, the peak amplifiers 23 and 24 are turned off, and the output impedance of the carrier amplifier 22 increases. As a result, the radio-frequency circuit 1 operates at high efficiency.

By contrast, in the high-power mode, the carrier amplifier 22 and the peak amplifiers 23 and 24 operate to output high-power signals, and the output impedances of the carrier amplifier 22 and the peak amplifiers 23 and 24 are relatively low. As a result, signal distortion is suppressed.

### [1.4 Comparison of Radio-Frequency Circuits According to Exemplary Embodiment and Comparative Example]

Next, the radio-frequency circuit 1 according to the present exemplary embodiment will be compared to a radio-frequency circuit 500 according to a comparative example.

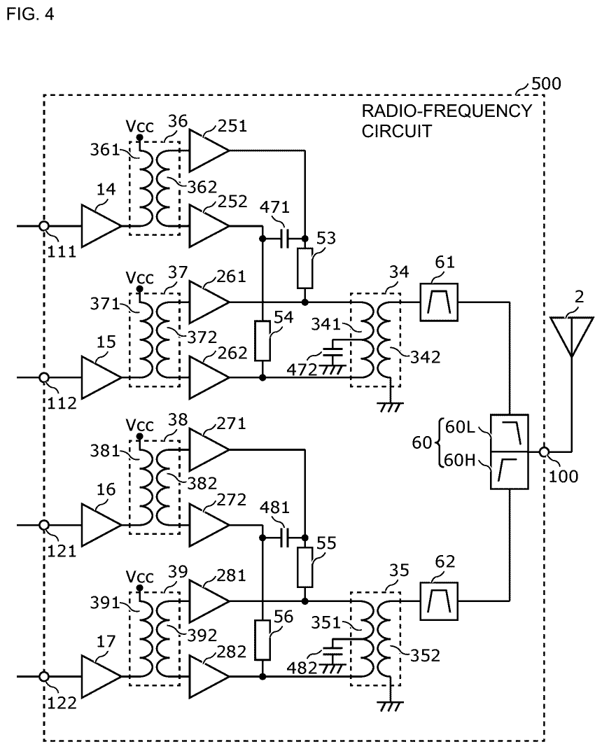

FIG. 4 is a circuit configuration diagram of the radio-frequency circuit 500 according to the comparative example. The radio-frequency circuit 500 according to the comparative example is a known Doherty amplifier circuit designed to amplify and transfer radio-frequency signals in the bands A and B. As illustrated in the drawing, the radio-frequency circuit 500 includes preamplifiers 14, 15, 16, and 17, carrier amplifiers 251, 252, 271, and 272, peak amplifiers 261, 262, 281, and 282, transformers 34, 35, 36, 37, 38, and 39, capacitors 471, 472, 481, and 482, phase shift lines 53, 54, 55, and 56, filters 61 and 62, a diplexer 60, input terminals 111, 112, 121, and 122, and an antenna connection terminal 100. The radio-frequency circuit 500 according to the comparative example differs from the radio-frequency circuit 1 according to the exemplary embodiment in that: (1) the peak amplifiers that amplify and transfer radio-frequency signals in the band A are different from the peak amplifiers that amplify and transfer radio-frequency signals in the band B; (2) the carrier amplifiers are of the differential amplification type. In the following, the radio-frequency circuit 500 according to the comparative example will be described, with a main focus on features that differ from the radio-frequency circuit 1 according to the exemplary embodiment.

A circuit that amplifies and transfers radio-frequency signals in the band A is formed by the preamplifiers 14 and 15, the carrier amplifiers 251 and 252, the peak amplifiers 261 and 262, the transformers 34, 36, and 37, the capacitors 471 and 472, the phase shift lines 53 and 54, and the filter 61.

Assuming the radio-frequency circuit 500 transfers signals in the band A in the high-power mode, the carrier amplifiers 251 and 252 operate in differential amplification (Class A or Class AB operation), and the peak amplifiers 261 and 262 operate in differential amplification (Class C operation). In this case, the current of the band-A differential signals transferred through the input terminal 111, the preamplifier 14, the transformer 36, the carrier amplifiers 251 and 252, and the phase shift lines 53 and 54 are combined with the current of the band-A differential signals transferred through the input terminal 112, the preamplifier 15, the transformer 37, and the peak amplifiers 261 and 262. The combined band-A signals are output from the antenna connection terminal 100 via the filter 61 and the low pass filter 60L.

By contrast, assuming the radio-frequency circuit 500 transfers signals in the band A in the middle/low-power mode, the carrier amplifiers 251 and 252 operate in differential amplification (Class A or Class AB operation), and the peak amplifiers 261 and 262 do not operate in amplification. In this case, the band-A signals transferred through the input terminal 111, the preamplifier 14, the transformer 36, the carrier amplifiers 251 and 252, the phase shift lines 53 and 54, and the transformer 34 are output from the antenna connection terminal 100 via the filter 61 and the low pass filter 60L.

A circuit that amplifies and transfers radio-frequency signals in the band B is formed by the preamplifiers 16 and 17, the carrier amplifiers 271 and 272, the peak amplifiers 281 and 282, the transformers 35, 38, and 39, the capacitors 481 and 482, the phase shift lines 55 and 56, and the filter 62.

Assuming the radio-frequency circuit 500 transfers signals in the band B in the high-power mode, the carrier amplifiers 271 and 272 operate in differential amplification (Class A or Class AB operation), and the peak amplifiers 281 and 282 operate in differential amplification (Class C operation). In this case, the current of the band-B differential signals transferred through the input terminal 121, the preamplifier 16, the transformer 38, the carrier amplifiers 271 and 272, and the phase shift lines 55 and 56 are combined with the current of the band-B differential signals transferred through the input terminal 122, the preamplifier 17, the transformer 39, and the peak amplifiers 281 and 282. The combined band-B signals are output from the antenna connection terminal 100 via the filter 62 and the high pass filter 60H.

By contrast, assuming the radio-frequency circuit 500 transfers signals in the band B in the middle/low-power mode, the carrier amplifiers 271 and 272 operate in differential amplification (Class A or Class AB operation), and the peak amplifiers 281 and 282 do not operate in amplification. In this case, the band-B signals transferred through the input terminal 121, the preamplifier 16, the transformer 38, the carrier amplifiers 271 and 272, the phase shift lines 55 and 56, and the transformer 35 are output from the antenna connection terminal 100 via the filter 62 and the high pass filter 60H.

As presented in the configuration described above, in the radio-frequency circuit 500 according to the comparative example, as compared to the radio-frequency circuit 1 according to the exemplary embodiment, the peak amplifiers 261 and 262, which amplify and transfer radio-frequency signals in the band A, and the peak amplifiers 282 and 282, which amplify and transfer radio-frequency signals in the band B, are individually provided. As a result, the radio-frequency circuit 500 according to the comparative example has more carrier amplifiers and peak amplifiers than the radio-frequency circuit 1 according to the exemplary embodiment. Accordingly, an increased number of preamplifiers and transformers are provided.

By contrast, in the radio-frequency circuit 1 according to the present exemplary embodiment, a single peak amplifier is shared as the peak amplifier used to transfer band-A signals and the peak amplifier used to transfer band-B signals. As such, amplifying and transferring radio-frequency signals in multiple bands can be achieved by a reduced number of carrier amplifiers and peak amplifiers. This configuration miniaturizes the radio-frequency circuit 1 and the communication device 4, which are capable of amplifying radio-frequency signals in multiple bands.

### [1.5 Relationship Between Individual Amplifier Sizes and Back-Off Level]

Next, the relationship between the sizes of individual amplifiers and the back-off level will be described.

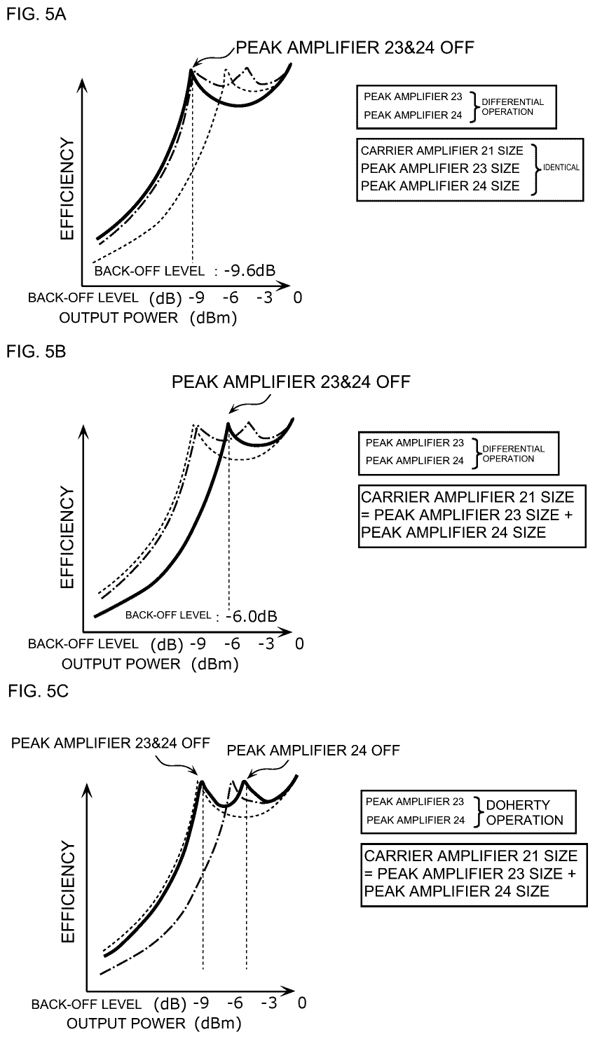

FIG. 5A is a graph illustrating the relationship between output power and efficiency in a first pattern of the radio-frequency circuit 1 according to the exemplary embodiment. FIG. 5B is a graph illustrating the relationship between output power and efficiency in a second pattern of the radio-frequency circuit 1 according to the exemplary embodiment. FIG. 5C is a graph illustrating the relationship between output power and efficiency in a third pattern of the radio-frequency circuit 1 according to the exemplary embodiment.

FIG. 5B illustrates the relationship between output power and efficiency assuming the size of the carrier amplifier 21 is equal to the sum of the size of the peak amplifier 23 and the size of the peak amplifier 24 (second pattern). In this case, provided that the back-off level indicates the power difference between the high power output region, in which the carrier amplifier 21 and the peak amplifiers 23 and 24 are on, and the low power output region, in which only the carrier amplifier 21 is on, the back-off level is −6 dB.

By contrast, FIG. 5A illustrates the relationship between output power and efficiency assuming the size of the carrier amplifier 21 is equal to the size of the peak amplifier 23, and the size of the carrier amplifier 21 is equal to the size of the peak amplifier 24 (first pattern). In this case, because the size of the peak amplifier 23 and the size of the peak amplifier 24 are larger than in the second pattern, the back-off level can be increased to −9.6 dB.

FIG. 5C illustrates the relationship between output power and efficiency assuming the size of the carrier amplifier 21 is equal to the sum of the size of the peak amplifier 23 and the size of the peak amplifier 24, and the peak amplifiers 23 and 24 operate in Doherty mode (third pattern). Specifically, the carrier amplifier 21 and the peak amplifiers 23 and 24 are on in the high power output region, the peak amplifier 24 is off in the middle power output region, and the peak amplifiers 23 and 24 are off in the low power output region. As such, the back-off level can be set at two levels.

The size of each amplifier is defined by the area of the region in which the amplifier transistor included in the amplifier is formed assuming the semiconductor integrated circuit (IC) or module substrate having the amplifier is viewed in plan view.

The size of each amplifier depends on the number of stages, cells, or fingers of the transistor that forms the amplifier. Thus, assuming the size is large, at least one of the following is satisfied: the number of transistor stages is relatively great and the number of transistor cells or fingers is relatively great.

The situation in which “two amplifiers are equal in size” also includes cases in which the two amplifiers are exactly equal in size, as well as cases in which the two amplifiers are substantially equal in size. Here, the amplifier size is expressed in terms of area (a measure of two-dimensional region). The situation in which two amplifiers are substantially equal in size refers to a situation in which the ratio of the difference between the two amplifier sizes to the size of a larger amplifier of the two amplifiers is less than or equal to 10%.

The area of the region in which an amplifier transistor is formed can be measured by recognizing the regions of N-type and P-type semiconductors in an image of the amplifier transistor captured by irradiating X-rays from the normal direction of the major surface of the semiconductor IC or module substrate.

In FIGS. 5A to 5C, the carrier amplifier 21 and the peak amplifiers 23 and 24 are compared with respect to size. The same applies to the size comparison among the carrier amplifier 22 and the peak amplifiers 23 and 24.

### [1.6 Circuit Configuration of Radio-Frequency Circuit 1A According to Modification].

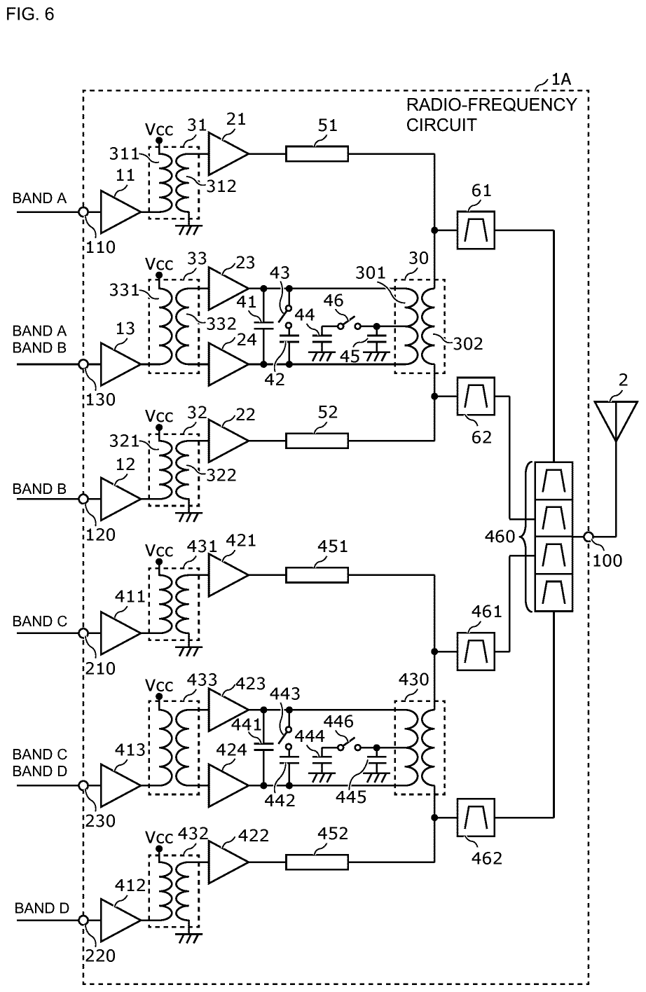

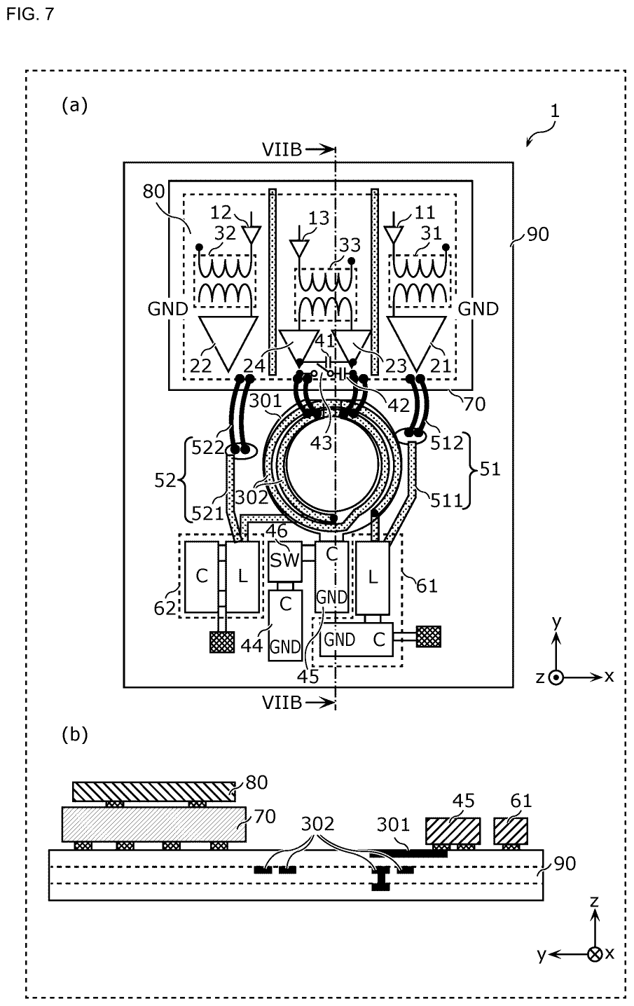

FIG. 6 is a circuit configuration diagram of a radio-frequency circuit 1A according to a modification. As illustrated in the drawing, the radio-frequency circuit 1A includes preamplifiers 11, 12, 13, 411, 412, and 413, carrier amplifiers 21, 22, 421, and 422, peak amplifiers 23, 24, 423, and 424, transformers 30, 31, 32, 33, 430, 431, 432, and 433, capacitors 41, 42, 44, 45, 441, 442, 444, and 445, switches 43, 46, 443, and 446, phase shift lines 51, 52, 451, and 452, filters 61, 62, 461, and 462, a quadplexer 460, input terminals 110, 120, 130, 210, 220, and 230, and an antenna connection terminal 100. The radio-frequency circuit 1A according to the present modification differs from the radio-frequency circuit 1 according to the exemplary embodiment in incorporating circuits designed to amplify and transfer radio-frequency signals in bands C and D, in addition to the bands A and B. In the following, the radio-frequency circuit 1A according to the present modification will be described, with a main focus on features that differ from the radio-frequency circuit 1 according to the exemplary embodiment.

A first transfer circuit that amplifies and transmits radio-frequency signals in the bands A and B is formed by the preamplifiers 11 to 13, the carrier amplifiers 21 and 22, the peak amplifiers 23 and 24, the transformers 30 to 33, the capacitors 41, 42, 44, and 45, the switches 43 and 46, the phase shift lines 51 and 52, and the filters 61 and 62, similar to the radio-frequency circuit 1 according to the exemplary embodiment.

A second transfer circuit that amplifies and transmits radio-frequency signals in the bands C and D is formed by the preamplifiers 411 to 413, the carrier amplifiers 421 and 422, the peak amplifiers 423 and 424, the transformers 430 to 433, the capacitors 441, 442, 444, and 445, the switches 443 and 446, the phase shift lines 451 and 452, and the filters 461 and 462.

The connection relationship among the circuit components constituting the second transfer circuit is the same as the connection relationship among the circuit components constituting the first transfer circuit, and the description thereof will not be repeated.

The quadplexer 460 includes four filters (a third filter, a fourth filter, a fifth filter, and a sixth filter). One terminal of each of the third to sixth filters is coupled to the antenna connection terminal 100. The other terminal of the third filter is coupled to the filter 61. The other terminal of the fourth filter is coupled to the filter 62. The other terminal of the fifth filter is coupled to the filter 461. The other terminal of the sixth filter is coupled to the filter 462. The third filter is a filter that has a pass band including the band A. The fourth filter is a filter that has a pass band including the band B. The fifth filter is a filter that has a pass band including the band C. The sixth filter is a filter that has a pass band including the band D.

With this connection configuration of the radio-frequency circuit 1A, the current of a signal in the band A output from the carrier amplifier 21 and the currents of differential signals in the band A output from the peak amplifiers 23 and 24 are combined, and the combined output signal is output from one end of the output-side coil 302. The current of a signal in the band B output from the carrier amplifier 22 and the currents of differential signals in the band B output from the peak amplifiers 23 and 24 are combined, and the combined output signal is output from the other end of the output-side coil 302. The current of a signal in the band C output from the carrier amplifier 421 and the currents of differential signals in the band C output from the peak amplifiers 423 and 424 are combined, and the combined output signal is output from one end of the output-side coil of the transformer 430. The current of a signal in the band D output from the carrier amplifier 422 and the currents of differential signals in the band D output from the peak amplifiers 423 and 424 are combined, and the combined output signal is output from the other end of the output-side coil of the transformer 430.

This configuration provides a compact circuit capable of amplifying radio-frequency signals in four bands.

### [2. Physical Configurations of Radio-Frequency Circuits 1 and 1A].

A physical configuration of the radio-frequency circuit 1 according to the present exemplary embodiment will be described with reference to FIG. 7.

FIG. 7 provides a plan view and a sectional view of the radio-frequency circuit 1 according to the exemplary embodiment. In FIG. 7, (a) is a plan view of the radio-frequency circuit 1, specifically a cutaway view of a major surface of a module substrate 90 from the positive side of the z-axis, and (b) is a sectional view of the radio-frequency circuit 1. The section of the radio-frequency circuit 1 in (b) of FIG. 7 is taken along line VIIB-VIIB line in (a) of FIG. 7. In (a) of FIG. 7, for ease of understanding the positional relationship among the amplifiers, transformers, capacitors, and switches, the individual circuit components are assigned corresponding symbols representing the function of each circuit component, although the symbols are not displayed on the actual amplifiers, transformers, capacitors, and switches. In FIG. 7, some wire lines connecting the module substrate 90 and the circuit components are not illustrated.

The radio-frequency circuit 1 illustrated in FIG. 7 may further include a resin member that covers the major surface of the module substrate 90 and some portions of the circuit components, and a shield electrode layer that covers the major surface of the resin member. The resin member and the shield electrode layer are not illustrated in FIG. 7.

In addition to the circuit configuration illustrated in FIG. 1, the radio-frequency circuit 1 also includes the module substrate 90 and a semiconductor IC 80. The diplexer 60 included in the radio-frequency circuit 1 may be disposed at the module substrate 90, although the diplexer 60 is not illustrated in FIG. 7.

The module substrate 90 is a substrate at which the circuit components constituting the radio-frequency circuit 1 are mounted. For example, a low temperature co-fired ceramics (LTCC) substrate having a layered structure of a plurality of dielectric layers, a high temperature co-fired ceramics (HTCC) substrate, a component-embedded substrate, a substrate including a redistribution layer (RDL), or a printed-circuit board is used as the module substrate 90.

The carrier amplifiers 21 and 22, the peak amplifiers 23 and 24, the preamplifiers 11, 12, and 13, the transformers 31, 32, and 33, the capacitors 41, 42, 44, and 45, the switches 43 and 46, and the filters 61 and 62 are disposed on the major surface of module substrate 90.

Among these components, the carrier amplifiers 21 and 22, the peak amplifiers 23 and 24, the preamplifiers 11, 12, and 13, the transformers 31, 32, and 33, the capacitors 41 and 42, and the switch 43 are included in a semiconductor IC 70 (an example of a first semiconductor IC).

Integrating the capacitors 41 and 42 and the switch 43 into the semiconductor IC 70 miniaturizes the radio-frequency circuit 1.

The carrier amplifiers 21 and 22, the peak amplifiers 23 and 24, the preamplifiers 11, 12, and 13, the transformers 31, 32, and 33, the capacitors 41 and 42, and the switch 43 are not necessarily included in the semiconductor IC 70 but may be individually disposed at the module substrate 90.

The semiconductor IC 80 is disposed on the major surface of the module substrate 90. The semiconductor IC 80 is an example of a second semiconductor IC. The semiconductor IC 80 includes an amplifier control circuit that controls the carrier amplifiers 21 and 22 and the peak amplifiers 23 and 24. The amplifier control circuit is operable to control, for example, bias currents supplied to the carrier amplifiers 21 and 22 and the peak amplifiers 23 and 24.

Each of the semiconductor ICs 70 and 80 may be made using, for example, complementary metal oxide semiconductor (CMOS). Specifically, the semiconductor ICs 70 and 80 may be manufactured using a silicon on insulator (SOI) process. Each of the semiconductor ICs 70 and 80 may be made of at least one of GaAs, SiGe, and GaN. The semiconductor material of the semiconductor ICs 70 and 80 is not limited to the materials presented above.

As illustrated in FIG. 7, the semiconductor ICs 70 and 80 are stacked in this order from the major surface of the module substrate 90.

This arrangement reduces the area and size of the radio-frequency circuit 1.

The input-side coil 301 of the transformer 30 is formed in a dielectric layer (a first dielectric layer) at the major surface of the module substrate 90. The output-side coil 302 of the transformer 30 and portions of the phase shift lines 51 and 52 are formed in a dielectric layer (a second dielectric layer) inside the module substrate 90.

The input-side coil 301 is formed by an annular planar conductor in the first dielectric layer. The output-side coil 302 is formed by an annular planar conductor in the second dielectric layer. The input-side coil 301 and the output-side coil 302 at least partially overlap assuming the module substrate 90 is viewed in plan view. This arrangement reduces the size of the transformer 30.

The phase shift line 51 is positioned on the outer right side with respect to the transformer 30 assuming the module substrate 90 is viewed in plan view. The phase shift line 51 is formed by a planar conductor 511 and a bonding wire 512. The bonding wire 512 is an example of a first bonding wire. The bonding wire 512 is coupled to the output terminal of the carrier amplifier 21. The planar conductor 511 is an example of a first transfer line. The planar conductor 511 is formed at the major surface of the module substrate 90 or inside the module substrate 90. One end of the planar conductor 511 is coupled to the bonding wire 512, and the other end of the planar conductor 511 is coupled to one end of the output-side coil 302.

The phase shift line 52 is positioned on the outer left side with respect to the transformer 30 assuming the module substrate 90 is viewed in plan view. The phase shift line 52 is formed by a planar conductor 521 and a bonding wire 522. The bonding wire 522 is an example of a second bonding wire. The bonding wire 522 is coupled to the output terminal of the carrier amplifier 22. The planar conductor 521 is an example of a second transfer line. The planar conductor 521 is formed at the major surface of the module substrate 90 or inside the module substrate 90. One end of the planar conductor 521 is coupled to the bonding wire 522, and the other end of the planar conductor 521 is coupled to the other end of the output-side coil 302.

Because the phase shift line 51 is disposed at the major surface of the module substrate 90 or inside the module substrate 90, and the phase shift line 52 is disposed at the major surface of the module substrate 90 or inside the module substrate 90, this arrangement miniaturizes the radio-frequency circuit 1.

Assuming the module substrate 90 is viewed in plan view, the carrier amplifier 21, the peak amplifier 23, the peak amplifier 24, and the carrier amplifier 22 are disposed on the major surface of the module substrate 90 in this order in a specific direction (the negative direction along the x-axis).

With this arrangement, the two phase shift lines 51 and 52 can be easily symmetrically positioned around the transformer 30. This arrangement thus achieves a simplified and highly precise placement of circuit components.

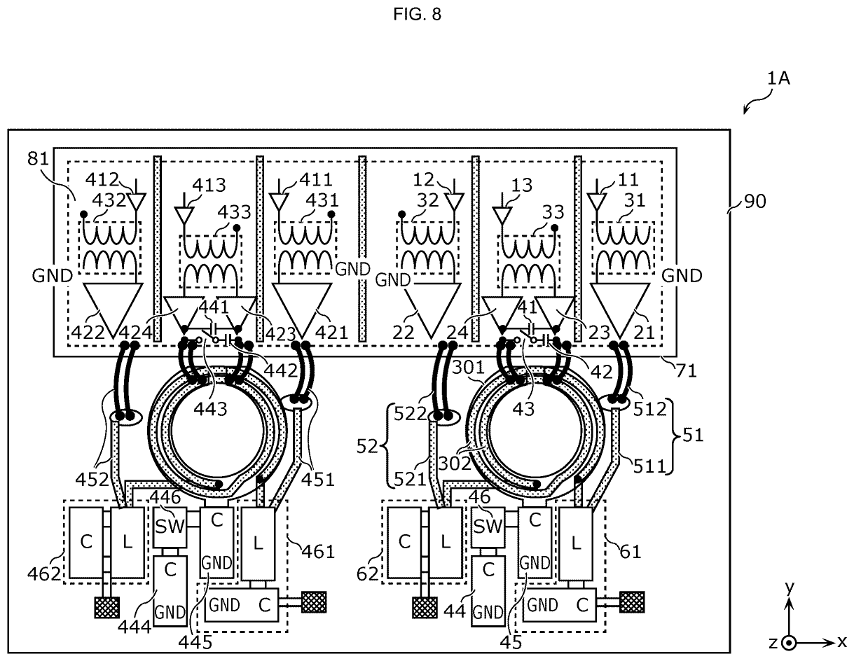

Next, a physical configuration of the radio-frequency circuit 1A according to the modification will be described with reference to FIG. 8.

FIG. 8 is a plan view of the radio-frequency circuit 1A according to the modification. FIG. 8 is a cutaway view of a major surface of a module substrate 90 from the positive side of the z-axis. In FIG. 8, for ease of understanding the positional relationship among the amplifiers, transformers, capacitors, and switches, the individual circuit components are assigned corresponding symbols representing the function of each circuit component, although the symbols are not displayed on the actual amplifiers, transformers, capacitors, and switches. In FIG. 8, some wire lines connecting the module substrate 90 and the circuit components are not illustrated.

The radio-frequency circuit 1A illustrated in FIG. 8 may further include a resin member that covers the major surface of the module substrate 90 and some portions of the circuit components, and a shield electrode layer that covers the major surface of the resin member. The resin member and the shield electrode layer are not illustrated in FIG. 8.

In addition to the circuit configuration illustrated in FIG. 6, the radio-frequency circuit 1A also includes the module substrate 90 and a semiconductor IC 81. The quadplexer 460 included in the radio-frequency circuit 1A may be disposed at the module substrate 90, although the quadplexer 460 is not illustrated in FIG. 8.

Compared to the physical configuration of the radio-frequency circuit 1 according to the exemplary embodiment, in the physical configuration of the radio-frequency circuit 1A according to the present modification, two transfer circuits (a first transfer circuit and a second transfer circuits) having the same functions as in the radio-frequency circuit 1 are disposed in a specific direction. In the following, the physical configuration of the radio-frequency circuit 1A according to the present modification will be described, with a main focus on features that differ from the physical configuration of the radio-frequency circuit 1 according to the exemplary embodiment.

The carrier amplifiers 21, 22, 421, and 422, the peak amplifiers 23, 24, 423, and 424, the preamplifiers 11, 12, 13, 411, 412, and 413, the transformers 31, 32, 33, 431, 432, and 433, the capacitors 41, 42, 44, 45, 441, 442, 444, and 445, the switches 43, 46, 443, and 446, and the filters 61, 62, 461, and 462 are disposed on the major surface of module substrate 90.

Among these components, the carrier amplifiers 21, 22, 421, and 422, the peak amplifiers 23, 24, 423, and 424, the preamplifiers 11, 12, 13, 411, 412, and 413, the transformers 31, 32, 33, 431, 432, and 433, the capacitors 41, 42, 441, and 442, and the switches 43 and 443 are included in a semiconductor IC 71 (an example of a first semiconductor IC).

Integrating the capacitors 41, 42, 441, and 442, and the switches 43 and 443 into the semiconductor IC 71 miniaturizes the radio-frequency circuit 1A.

The semiconductor IC 81 is disposed on the major surface of the module substrate 90. The semiconductor IC 81 is an example of a second semiconductor IC. The semiconductor IC 81 includes an amplifier control circuit that controls the carrier amplifiers 21, 22, 421, and 422 and the peak amplifiers 23, 24, 423, and 424. The amplifier control circuit is operable to control, for example, bias currents supplied to the carrier amplifiers 21, 22, 421, and 422 and the peak amplifiers 23, 24, 423, and 424.

As illustrated in FIG. 8, the semiconductor ICs 71 and 81 are stacked in this order from the major surface of the module substrate 90.

This arrangement reduces the area and size of the radio-frequency circuit 1A.

The input-side coil 301 of the transformer 30 and the input-side coil of the transformer 430 are formed in a dielectric layer (a first dielectric layer) at the major surface of the module substrate 90. The output-side coil 302 of the transformer 30, the output-side coil of the transformer 430, and portions of the phase shift lines 51, 52, 451, and 452 are formed in a dielectric layer (a second dielectric layer) inside the module substrate 90.

The input-side coil and the output-side coil of the transformer 430 at least partially overlap assuming the module substrate 90 is viewed in plan view. This arrangement reduces the size of the transformer 430.

The phase shift line 451 is positioned on the outer right side with respect to the transformer 430 assuming the module substrate 90 is viewed in plan view. The phase shift line 451 is formed by a first transfer line and a first bonding wire. The phase shift line 452 is positioned on the outer left side with respect to the transformer 430 assuming the module substrate 90 is viewed in plan view. The phase shift line 452 is formed by a second transfer line and a second bonding wire. Because the phase shift line 451 is disposed at the major surface of the module substrate 90 or inside the module substrate 90, and the phase shift line 452 is disposed at the major surface of the module substrate 90 or inside the module substrate 90, this arrangement miniaturizes the radio-frequency circuit 1A.

Assuming the module substrate 90 is viewed in plan view, the carrier amplifier 421, the peak amplifier 423, the peak amplifier 424, and the carrier amplifier 422 are positioned on the major surface of the module substrate 90 in this order in a specific direction (the negative direction along the x-axis).

With this arrangement, the two phase shift lines 451 and 452 can be easily symmetrically positioned around the transformer 430. This arrangement thus achieves a simplified and highly precise placement of circuit components.

### [3. Effects]

As described above, the radio-frequency circuit 1 according to the present exemplary embodiment includes the carrier amplifier 21 configured to amplify radio-frequency signals in the band A, the carrier amplifier 22 configured to amplify radio-frequency signals in the band B, the peak amplifier 23 configured to amplify radio-frequency signals in the band A and radio-frequency signals in the band B, the peak amplifier 24 configured to amplify radio-frequency signals in the band A and radio-frequency signals in the band B, the transformer 30 having the input-side coil 301 and the output-side coil 302, and the phase shift lines 51 and 52. The output terminal of the peak amplifier 23 is coupled to one end of the input-side coil 301. The output terminal of the peak amplifier 24 is coupled to the other end of the input-side coil 301. The output terminal of the carrier amplifier 21 is coupled to one end of the phase shift line 51. The output terminal of the carrier amplifier 22 is coupled to one end of the phase shift line 52. The other end of the phase shift line 51 is coupled to one end of the output-side coil 302. The other end of the phase shift line 52 is coupled to the other end of the output-side coil 302.

This configuration reduces carrier amplifiers and peak amplifiers to amplify and transfer radio-frequency signals in multiple bands. This configuration thus miniaturizes the radio-frequency circuit 1, which is capable of amplifying radio-frequency signals in multiple bands.

In an example, the radio-frequency circuit 1 may further include the capacitor 42 coupled between the output terminal of the peak amplifier 23 and the output terminal of the peak amplifier 24, and include the switch 43 coupled to the capacitor 42, between the output terminal of the peak amplifier 23 and the output terminal of the peak amplifier 24.

With this configuration, the harmonic waves in a specific band of interest can be suppressed by opening or closing the switch 43, thereby widening the range of radio-frequency signals that can be transferred.

In an example, in the radio-frequency circuit 1, to transfer radio-frequency signals in the band A, the switch 43 may be closed, and to transfer radio-frequency signals in the band B, the switch 43 may be open.

This configuration suppresses harmonic waves in a specific band of interest, thereby widening the range of radio-frequency signals that can be transferred.

In an example, the radio-frequency circuit 1 may further includes the capacitor 44 coupled between the input-side coil 301 and ground, and the switch 46 coupled to the capacitor 44, between the input-side coil 301 and ground.

This configuration reduces common mode noise in a specific band of interest by opening or closing the switch 46, thereby widening the range of radio-frequency signals that can be transferred.

In an example, in the radio-frequency circuit 1, to transfer radio-frequency signals in the band A, the switch 46 may be closed, and to transfer radio-frequency signals in the band B, the switch 46 may be open.

This configuration reduces common mode noise in a specific band of interest, thereby widening the range of radio-frequency signals that can be transferred.

In an example, the radio-frequency circuit 1 may further include the filter 61 coupled to one end of the output-side coil 302, having a pass band that includes the band A, and the filter 62 coupled to the other end of the output-side coil 302, having a pass band that includes the band B.

This configuration improves the signal quality of radio-frequency signals in the bands A and B output from the antenna connection terminal 100.

In an example, the radio-frequency circuit 1 may further include the module substrate 90. Assuming the module substrate 90 is viewed in plan view, the carrier amplifier 21, the peak amplifier 23, the peak amplifier 24, and the carrier amplifier 22 may be disposed on the major surface of the module substrate 90 in this order in a specific direction.

With this arrangement, the two phase shift lines 51 and 52 can be easily symmetrically positioned around the transformer 30. This arrangement thus achieves a simplified and highly precise placement of circuit components.

In an example, in the radio-frequency circuit 1, the module substrate 90 may have multiple dielectric layers. The input-side coil 301 may be at least partially formed in the first dielectric layer among the multiple dielectric layers. The output-side coil 302 may be at least partially formed in the second dielectric layer among the multiple dielectric layers. Assuming the module substrate 90 is viewed in plan view, the input-side coil 301 and the output-side coil 302 may at least partially overlap.

This arrangement reduces the size of the transformer 30.

In an example, in the radio-frequency circuit 1, the phase shift line 51 may include the bonding wire 512 coupled to the output terminal of the carrier amplifier 21, and the planar conductor 511 formed at the major surface of the module substrate 90 or inside the module substrate 90, having one end coupled to the bonding wire 512 and another end coupled to one end of the output-side coil 302. The phase shift line 52 may include the bonding wire 522 coupled to the output terminal of the carrier amplifier 22, and the planar conductor 521 formed at the major surface of the module substrate 90 or inside the module substrate 90, having one end coupled to the bonding wire 522 and another end coupled to the other end of the output-side coil 302.

Because the phase shift line 51 is disposed at the major surface of the module substrate 90 or inside the module substrate 90, and the phase shift line 52 is disposed at the major surface of the module substrate 90 or inside the module substrate 90, this arrangement miniaturizes the radio-frequency circuit 1.

In an example, the radio-frequency circuit 1 may further include the amplifier control circuit configured to control the carrier amplifiers 21 and 22 and the peak amplifiers 23 and 24. The carrier amplifiers 21 and 22 and the peak amplifiers 23 and 24 may be included in the semiconductor IC 70 disposed on the major surface of the module substrate 90. The amplifier control circuit may be included in the semiconductor IC 80 disposed on the major surface of the module substrate 90. The semiconductor ICs 70 and 80 may be stacked in this order from the major surface.

This arrangement reduces the area and size of the radio-frequency circuit 1.

In an example, in the radio-frequency circuit 1, the capacitor 42 and the switch 43 may be included in the semiconductor IC 70.

This configuration miniaturizes the radio-frequency circuit 1.

The communication device 4 according to the present exemplary embodiment includes the RFIC 3 configured to process radio-frequency signals and the radio-frequency circuit 1 configured to transfer radio-frequency signals between the RFIC 3 and the antenna 2.

This configuration enables the communication device 4 to achieve the same effects as the radio-frequency circuit 1.

### Other Exemplary Embodiments

The radio-frequency circuit and the communication device according to an exemplary embodiment of the present disclosure have been described by using the exemplary embodiment and modification, but the radio-frequency circuit and the communication device according to the present disclosure are not limited to the exemplary embodiment and modification. The present disclosure also embraces other exemplary embodiments implemented as any combination of the constituent elements of the exemplary embodiment and modification, other modifications obtained by making various modifications to the exemplary embodiment that occur to those skilled in the art without departing from the scope of the present disclosure, and various hardware devices including the radio-frequency circuit or communication device according to the present disclosure.

For example, in the radio-frequency circuit and communication device according to the exemplary embodiment and modification described above, other circuit elements and wire lines may be inserted in the paths connecting the circuit elements and signal paths that are illustrated in the drawings.

### INDUSTRIAL APPLICABILITY

The present disclosure can be used as a radio-frequency circuit provided at the front-end that supports multiple bands, in a wide variety of communication devices such as mobile phones.

### REFERENCE SIGNS LIST

1, 1A, 500 radio-frequency circuit
2 antenna
3 RF signal processing circuit (RFIC)
4 communication device
11, 12, 13, 14, 15, 16, 17, 411, 412, 413 preamplifier
21, 22, 251, 252, 271, 272, 421, 422 carrier amplifier
23, 24, 261, 262, 281, 282, 423, 424 peak amplifier
30, 31, 32, 33, 34, 35, 36, 37, 38, 39, 430, 431, 432, 433 transformer
41, 42, 44, 45, 441, 442, 444, 445, 471, 472, 481, 482 capacitor
43, 46, 443, 446 switch
51, 52, 53, 54, 55, 56, 451, 452 phase shift line
60 diplexer
60H high pass filter
60L low pass filter
61, 62, 461, 462 filter
70, 71, 80, 81 semiconductor IC
90 module substrate
100 antenna connection terminal
110, 111, 112, 120, 121, 122, 130, 210, 220, 230 input terminal
301 input-side coil
302 output-side coil
311, 321, 331, 341, 351, 361, 371, 381, 391 primary coil
312, 322, 332, 342, 352, 362, 372, 382, 392 secondary coil
460 quadplexer
511, 521 planar conductor
512, 522 bonding wire

1. A radio-frequency circuit comprising:
a first carrier amplifier configured to amplify a radio-frequency signal in a first band;
a second carrier amplifier configured to amplify a radio-frequency signal in a second band;
a first peak amplifier configured to amplify a radio-frequency signal in the first band and a radio-frequency signal in the second band;
a second peak amplifier configured to amplify a radio-frequency signal in the first band and a radio-frequency signal in the second band;
a transformer having an input-side coil and an output-side coil; and
a first phase shifter circuit and a second phase shifter circuit, wherein
an output terminal of the first peak amplifier is coupled to one end of the input-side coil,
an output terminal of the second peak amplifier is coupled to another end of the input-side coil,
an output terminal of the first carrier amplifier is coupled to one end of the first phase shifter circuit,
an output terminal of the second carrier amplifier is coupled to one end of the second phase shifter circuit,
another end of the first phase shifter circuit is coupled to one end of the output-side coil, and
another end of the second phase shifter circuit is coupled to another end of the output-side coil.

2. The radio-frequency circuit according to claim 1, further comprising:
a first capacitor coupled between the output terminal of the first peak amplifier and the output terminal of the second peak amplifier; and
a first switch coupled to the first capacitor, between the output terminal of the first peak amplifier and the output terminal of the second peak amplifier.

3. The radio-frequency circuit according to claim 2, further comprising:
a second capacitor coupled between the input-side coil and ground; and
a second switch coupled to the second capacitor, between the input-side coil and ground.

4. The radio-frequency circuit according to claim 3, further comprising:
a first filter coupled to the one end of the output-side coil, the first filter having a pass band that includes the first band; and
a second filter coupled to the other end of the output-side coil, the second filter having a pass band that includes the second band.

5. The radio-frequency circuit according to claim 2, further comprising:
a module substrate, wherein
the first carrier amplifier, the first peak amplifier, the second peak amplifier, and the second carrier amplifier are included in a first semiconductor IC disposed on the major surface of the module substrate, and
the first capacitor and the first switch are included in the first semiconductor IC.

6. The radio-frequency circuit according to claim 5, wherein the first band ranges from 3300 Mhz to 4200 MHz, and the second band ranges from 4400 Mhz to 5000 MHz.

7. The radio-frequency circuit according to claim 6 further comprising a diplexer connected to the first filter and the second filter.

8. The radio-frequency circuit according to claim 7, wherein the diplexer includes a high pass filter and a low pass filter.

9. The radio-frequency circuit according to claim 1, further comprising:
a module substrate, wherein
in plan view of the module substrate, the first carrier amplifier, the first peak amplifier, the second peak amplifier, and the second carrier amplifier are disposed on a major surface of the module substrate in this order in a specific direction.

10. The radio-frequency circuit according to claim 9, wherein
the module substrate includes a plurality of dielectric layers,
at least a portion of the input-side coil is formed in a first dielectric layer among the plurality of dielectric layers,
at least a portion of the output-side coil is formed in a second dielectric layer among the plurality of dielectric layers, and
in plan view of the module substrate, the at least a portion of the input-side coil overlaps the at least a portion of the output-side coil.

11. The radio-frequency circuit according to claim 10, wherein the first phase shifter circuit includes
a first bonding wire coupled to the output terminal of the first carrier amplifier, and
a first transfer line formed at the major surface of the module substrate or inside the module substrate, the first transfer line having one end coupled to the first bonding wire and another end coupled to the one end of the output-side coil, and
the second phase shifter circuit includes
a second bonding wire coupled to the output terminal of the second carrier amplifier, and
a second transfer line formed at the major surface of the module substrate or inside the module substrate, the second transfer line having one end coupled to the second bonding wire and another end coupled to the other end of the output-side coil.

12. The radio-frequency circuit according to claim 11, further comprising:
an amplifier control circuit configured to control the first carrier amplifier, the first peak amplifier, the second peak amplifier, and the second carrier amplifier, wherein
the first carrier amplifier, the first peak amplifier, the second peak amplifier, and the second carrier amplifier are included in a first semiconductor integrated circuit (IC) disposed on the major surface of the module substrate,
the amplifier control circuit is included in a second semiconductor IC disposed on the major surface of the module substrate, and
the first semiconductor IC and the second semiconductor IC are stacked in this order from the major surface.

13. The radio-frequency circuit according to claim 1 further comprising:
a third carrier amplifier configured to amplify a radio-frequency signal in a third band;
a fourth carrier amplifier configured to amplify a radio-frequency signal in a fourth band;
a third peak amplifier configured to amplify a radio-frequency signal in the third band and a radio-frequency signal in the fourth band;
a fourth peak amplifier configured to amplify a radio-frequency signal in the third band and a radio-frequency signal in the fourth band;
a second transformer having an second input-side coil and an second output-side coil; and
a third phase shifter circuit and a fourth phase shifter circuit, wherein
an output terminal of the third peak amplifier is coupled to one end of the second input-side coil,
an output terminal of the fourth peak amplifier is coupled to another end of the second input-side coil,
an output terminal of the third carrier amplifier is coupled to one end of the third phase shifter circuit,
an output terminal of the fourth carrier amplifier is coupled to one end of the third phase shifter circuit,
another end of the first phase shifter circuit is coupled to one end of the second output-side coil, and
another end of the fourth phase shifter circuit is coupled to another end of the second output-side coil.

14. The radio-frequency circuit according to claim 13, further comprising:
a third capacitor coupled between the output terminal of the third peak amplifier and the output terminal of the fourth peak amplifier; and
a third switch coupled to the third capacitor, between the output terminal of the third peak amplifier and the output terminal of the fourth peak amplifier.

15. The radio-frequency circuit according to claim 14, further comprising:
a fourth capacitor coupled between the second input-side coil and ground; and
a fourth switch coupled to the fourth capacitor, between the second input-side coil and ground.

16. The radio-frequency circuit according to claim 15, further comprising:
a third filter coupled to the one end of the second output-side coil, the third filter having a pass band that includes the third band; and
a fourth filter coupled to the other end of the second output-side coil, the fourth filter having a pass band that includes the fourth band.

17. A computer readable circuit that includes:
a first carrier amplifier;
a second carrier amplifier;
a first peak amplifier;
a second peak amplifier;
a transformer having an input-side coil and an output-side coil; and
a first phase shifter circuit and a second phase shifter circuit,
a first capacitor coupled between the output terminal of the first peak amplifier and the output terminal of the second peak amplifier; and
a first switch coupled to the first capacitor, between the output terminal of the first peak amplifier and the output terminal of the second peak amplifier,
a radio frequency integrated circuit (RFIC) includes a an amplifier control circuit,
wherein the amplifier control circuit switches the first switch to be closed and the RFIC transmits a first band high-frequency signal, or the amplifier control circuit switches the first switch to be opened and the RFIC transmits the second band high-frequency signal.

18. The computer readable circuit according to claim 17 further comprising:
a second capacitor coupled between the input-side coil and ground; and
a second switch coupled to the second capacitor, between the input-side coil and ground,
wherein the amplifier control circuit switches the second switch to be closed and the RFIC transmits a first band high-frequency signal, or the amplifier control circuit switches the first switch to be opened and the RFIC transmits the second band high-frequency signal.

19. The computer readable circuit according to claim 17, wherein the first band ranges from 3300 Mhz to 4200 MHz, and the second band ranges from 4400 Mhz to 5000 MHz.

20. A communication device comprising:
a signal processing circuit configured to process a radio-frequency signal,
an antenna transmits the radio-frequency signal; and
a radio-frequency circuit configured to transfer the radio-frequency signal between the signal processing circuit and an antenna,
wherein the radio frequency circuit includes a first carrier amplifier configured to amplify a radio-frequency signal in a first band;
a second carrier amplifier configured to amplify a radio-frequency signal in a second band;
a first peak amplifier configured to amplify a radio-frequency signal in the first band and a radio-frequency signal in the second band;
a second peak amplifier configured to amplify a radio-frequency signal in the first band and a radio-frequency signal in the second band;
a transformer having an input-side coil and an output-side coil; and
a first phase shifter circuit and a second phase shifter circuit, wherein
an output terminal of the first peak amplifier is coupled to one end of the input-side coil,
an output terminal of the second peak amplifier is coupled to another end of the input-side coil,
an output terminal of the first carrier amplifier is coupled to one end of the first phase shifter circuit,
an output terminal of the second carrier amplifier is coupled to one end of the second phase shifter circuit,
another end of the first phase shifter circuit is coupled to one end of the output-side coil, and
another end of the second phase shifter circuit is coupled to another end of the output-side coil.
